(19) United States
(12) Patent Application Publication
(10) Pub. No.: US 2013/0221329 A1
(43) Pub. Date: Aug. 29, 2013

(54) Graphene Device

(71) Applicants: Qingqing Liang, Lagrangeville, NY (US); Huicai Zhong, San Jose, CA (US); Huilong Zhu, Poughkeepsie, NY (US); Zhi Jin, Beijing (CN); Xinyu Liu, Beijing (CN); Tianchun Ye, Beijing (CN)

(72) Inventors: Qingqing Liang, Lagrangeville, NY (US); Huicai Zhong, San Jose, CA (US); Huilong Zhu, Poughkeepsie, NY (US); Zhi Jin, Beijing (CN); Xinyu Liu, Beijing (CN); Tianchun Ye, Beijing (CN)

(21) Appl. No.: 13/582,431

(22) PCT Filed: Mar. 29, 2012
(86) PCT No.: PCT/CN12/00402

§ 371 Date: Sep. 3, 2012

(30) Foreign Application Priority Data
Feb. 29, 2012 (CN) 201210050646.1

(51) Int. Cl. H01L 29/66

(52) U.S. Cl. CPC H01L 29/66977
USPC 257/29

(57) ABSTRACT

An embodiment of the invention discloses a graphene device comprising a plurality of graphene channels and a gate, wherein one end of all the graphene channels is connected to one terminal, all the graphene channels are in contact with and electrically connected with the gate, and the angles between the graphene channels and the gate are mutually different. Due to a different incident wave angle for a different graphene channel, each of the graphene channels has a different tunneling probability, each of the graphene channels has a different conduction condition, and the graphene device may be used as a device such as a multiplexer or a demultiplexer, etc.

### CROSS REFERENCE

This application is a National Phase application of, and claims priority to, PCT Application No. PCT/CN2012/000402, filed on Mar. 29, 2012, entitled “A graphene device”, which claimed priority to Chinese Application No. 201210050646.1, filed on Feb. 29, 2012. Both the PCT Application and Chinese Application are incorporated herein by reference in their entireties.

### FIELD OF THE INVENTION

The invention relates to the field of designing an integrated circuit, and in particular, to a graphene device.

### BACKGROUND OF THE INVENTION

Currently, the design of an integrated circuit is mostly a CMOS device based on a silicon semiconductor, whereas with the development of science and technology, a higher requirement is raised for the performance of the integrated circuit such as speed, and it is to develop a new material system with a higher carrier mobility and a new technical means to further extend the Moore Law and Beyond Si-CMOS and promote the development of the integrated circuit technology.

The graphene material receives an extensive attention because of its excellent physical properties, such as its high carrier mobility, high electrical conductivity and high thermal conductivity, etc., and is a kind of carbon-based material which people feel very optimistic about. Although the graphene material shows many excellent physical characteristics, how to design a device/circuit based on grapheme, such as the design of a multiplexer and a demultiplexer, is still a key point under research.

### SUMMARY OF THE INVENTION

The problem to be resolved by the invention is to provide a graphene device, and to realize a design of a multiplexer/demultiplexer device base on grapheme.

To achieve the object above mentioned, an embodiment of the invention provides the following technical solution.

A graphene device comprising a plurality of graphene channels and at least one gate, wherein one end of each of the plurality of graphene channels is connected to one terminal, all the plurality of graphene channels are in contact with and electrically connected with the gate, and the angles between each of the plurality of graphene channels and the gate are different.

Optionally, the plurality of graphene channels are radially distributed from the terminal.

Optionally, the graphene device comprises one gate.

Optionally, the graphene device comprises a plurality of gates, and each of the plurality of gates are in contact and electrically connected with one or more different graphene channels, respectively.

Optionally, the graphene channels are single-layer graphene thin films.

Optionally, the terminal is an input end, and each of the other ends of the graphene channels is connected to different output ends, respectively.

Optionally, the terminal is an output end, and each of the other ends of the graphene channels is connected to different input ends, respectively.

As compared to the prior art, the above technical solution has the following advantages.

In the graphene device according to the embodiment of the invention, the graphene channels are in contact with and electrically connected with the gate, the angles between the graphene channels and the gate are mutually different, and thus, due to a different incident wave angle for a different graphene channel, each of the graphene channels has a different tunneling probability, each of the graphene channels has a different conduction condition, and the graphene device may be used as a device such as a multiplexer or a demultiplexer, etc.

### BRIEF DESCRIPTION OF THE DRAWINGS

The above and other objects, features and advantages of the invention will be clearer by illustration of the accompanying drawings. Throughout the drawings, like reference signs denote like parts. The drawings are not intentionally proportionately scaled and drawn according to the actual size, and the key point focuses on showing the gist of the invention.

FIG. 1 is a structurally schematic view of a graphene device according to an embodiment of the invention;

FIG. 2 is a structurally schematic view of a graphene device according to a further embodiment of the invention;

FIG. 3 is a schematic view of the incident wave angle θ of a graphene material; and

FIG. 4 is a graph of the tunneling probability varying with the incident wave angle θ at different barrier heights.

### DETAILED DESCRIPTION OF THE INVENTION

In order to enable the above objects, features and advantages of the invention more apparent and easy to understand, the particular embodiments of the invention will be described in detail with respect to the accompanying drawings hereinafter.

In the following description many particular details are elucidated to facilitate a sufficient understanding of the invention, however, the invention may also be implemented in other ways than those described herein, those skilled in the art may make a similar generalization without departing from the connotation of the invention, and therefore the invention is not limited by the following disclosed particular embodiments.

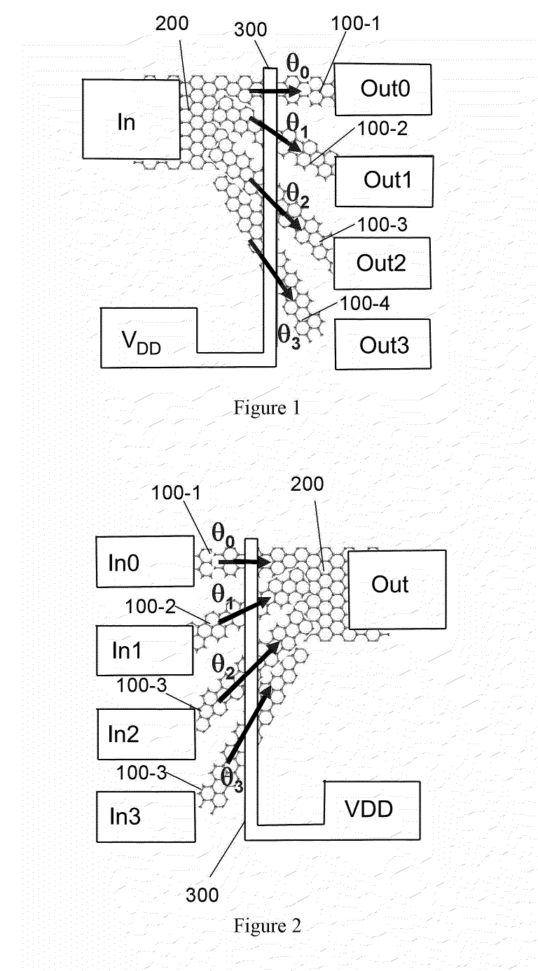

With respect to FIGS. 1 and 2, the invention proposes a graphene device comprising a plurality of graphene channels 100-1-100-4 and a gate 300, wherein one end of all the graphene channels 100-1-100-4 is connected to one terminal 200, all the graphene channels 100-1-100-4 are in contact with and electrically connected with the gate 300, and the angles θ₀-θ₃ between the graphene channels 100-1-100-4 and the gate 300 are mutually different.

It is shown from a study that for a graphene material, when an electron passes through a barrier, its tunneling probability is related to the angle between an incident wave and the barrier, and the tunneling probability is 1, namely, 100% tunneling, only if the barrier height and the incident wave angle take certain values.

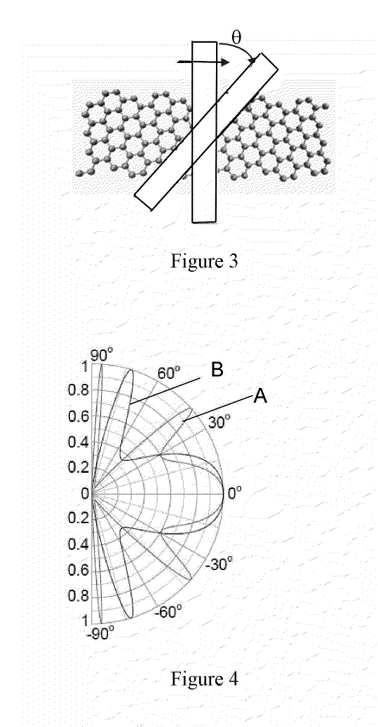

As shown in FIG. 3, an incident wave angle θ is the angle between an incident wave and a barrier. As shown in FIG. 4, there is plotted a graph of the tunneling probability varying with the incident wave angle θ at different barrier heights (referring to M. I. Katsnelson, et. Al., Nature Physics 2, pp. 620-625, 2006), wherein the curve A corresponds to a barrier height of 200 mv, and the curve B corresponds to a barrier height of 285 mv. It can be seen that at different barrier heights, only the tunneling probability at a particular angle is 1, for example, when the angle is about 0°, +/−40° at a barrier height of 200 mv, or when the angle is at about 0°, +/−70° at a barrier height of 285 mv. That is to say, a complete tunneling can be achieved at a particular incident wave angle θ at one barrier height.

In the graphene device of the invention, one end of a plurality of graphene channels is connected to one terminal, which is equivalent to the plurality of graphene channels being loaded with one barrier when the terminal has a potential; the graphene channels are in contact with and electrically connected with the gate and the angles between the graphene channels and the gate are mutually different, which is equivalent to the incident wave angles of different graphene channels being different. Thus, each of the graphene channels has a different tunneling probability, i.e., each of the graphene channels has a different conduction condition. When there is a potential at the connected one terminal, some channels are conductive and some are non-conductive due to different tunneling probabilities. Depending on the different angles when designed, the number of the conductive channels may be one or more. Therefore, the graphene device of the invention may be used as a multi-channel selective device, for example, a device such as a multiplexer or a demultiplexer, etc, the design of which is simple and the performance of which possesses such a feature as a high speed and a low power consumption due to a graphene material being adopted for design.

In the invention, the graphene channels are in contact with and electrically connected with the gate, namely, directly electrically connected with the gate. In an embodiment of the invention, the angle between the graphene channels and the gate, and the layout of the graphene channels and the gate, may be designed according to the requirements of a particular circuit. In some embodiments, as shown in FIG. 1, the graphene channels are distributed radially from the terminal, and one gate passes through all the graphene channels, such that the incident wave angles thereof are θ₀, θ₁, θ₂, θ₃, respectively, and a complete tunneling will be achieved at a corresponding different angle under the different angles. In other embodiments, the number of the gates may be a plurality (not shown in the figures), and they are in contact with and electrically connected with different graphene channels respectively. For example, there are two gates, four graphene channels, one gate is electrically connected with two of the graphene channels, and the other gate is electrically connected with the other two of the graphene channels, to be adapted to the requirements of a different circuit design. Here is only an example, and all those within the range covered by the idea of the invention fall within the protective scope of the invention.

As shown in FIG. 1, there is depicted a demultiplexer according to an embodiment of the invention. A demultiplexer is also called a data distributor, a circuit capable of transmit one input data to any one of m output ends as needed. In this embodiment, the terminal 200 of the graphene device is connected to one input end: In, the other ends of the graphene channels are connected to different output ends: Out0, Out1, Out2, Out3, respectively, and the gate 300 may be connected to a power supply V_{DD}. As such, when the input signal (voltage) of the input end (In) takes a different value, only the graphene channel at a corresponding angle is conductive, which implements data transmission to one output end and therefore realizes the function of the demultiplexer. In the design of the demultiplexer, it can be designed according to the corresponding relationship between the signal of a different input end and the angle between the graphene channel corresponding to the input end and the gate. When the signal of the input end In varies, a certain graphene channel for which the signal of the input end In matches the incident wave angle is made conductive, thereby realizing the function of the demultiplexer.

As shown in FIG. 2, there is depicted a multiplexer according to an embodiment of the invention. A multiplexer is also called a data selector, a circuit capable of selecting out any one of multiple ways as needed in the course of multi-way data transmission. In this embodiment, the terminal 200 of the graphene device is connected to one output end: Out, the other ends of the graphene channels are connected to different input ends: In 0, In 1, In 2, In 3, respectively, and the gate 300 may be connected to a power supply V_{DD}. As such, each of the graphene channels corresponds to an input end and an angle. When all the input ends are connected to input signals (voltage) together, only the graphene channel for which the input end voltage matches the angle is conductive, which implements data output of a certain way and therefore realizes the function of the multiplexer. In the design of the multiplexer, the angel between the graphene channel corresponding to an input end and the gate can be designed according to the requirements of the signal of the input end. In a situation as required, the required graphene channel for which the signal of the input end matches the incident wave angle is made conductive, thereby realizing the function of the multiplexer.

The above embodiments are applications of the graphene device of the invention, however, the invention is not limited thereto, and may also be applied in other data selection circuits.

What are described above are only preferred embodiments of the invention, and not intended to make any formal restrictions of the invention.

While the invention has been disclosed above in preferred embodiments, those embodiments are not used to define the invention. Any one skilled in the art may make many variations and modifications to the technical solution of the invention, or amend it into equivalent embodiments with equivalent changes using the approaches and technical content disclosed above, without departing from the scope of the technical solution of the invention. Therefore, all the content not departing from the technical solution of the invention, and any simple amendments, equivalent changes and modifications to the previous embodiments according to the technical essence of the invention, fall within the protective scope of the technical solution of the invention.

1. A graphene device, comprising:
a plurality of graphene channels and at least one gate, wherein one end of each of the plurality of graphene channels is connected to one terminal, all the plurality of graphene channels are in contact with and electrically connected with the gate, and the angles between each of the plurality of graphene channels and the gate are different.

2. The graphene device as claimed in claim 1, wherein the plurality of graphene channels are radially distributed from the terminal.

3. The graphene device as claimed in claim 1, wherein the graphene device comprises one gate.

4. The graphene device as claimed in claim 1, wherein the graphene device comprises a plurality of gates, and each of the plurality of gates are in contact and electrically connected with one or more different graphene channels, respectively.

5. The graphene device as claimed in any one of claims 1, wherein the graphene channels are single-layer graphene thin films.

6. The graphene device as claimed in any one of claims 1, wherein the terminal is an input end, and each of the other ends of the graphene channels is connected to different output ends, respectively.

7. The graphene device as claimed in any one of claims 1, wherein the terminal is an output end, and each of the other ends of the graphene channels is connected to different input ends, respectively.

8. The graphene device as claimed in claim 2, wherein the graphene channels are single-layer graphene thin films.

9. The graphene device as claimed in claim 2, wherein the terminal is an input end, and each of the other ends of the graphene channels is connected to different output ends, respectively.

10. The graphene device as claimed in claim 2, wherein the terminal is an output end, and each of the other ends of the graphene channels is connected to different input ends, respectively.

11. The graphene device as claimed in claim 3, wherein the graphene channels are single-layer graphene thin films.

12. The graphene device as claimed in claim 3, wherein the terminal is an input end, and each of the other ends of the graphene channels is connected to different output ends, respectively.

13. The graphene device as claimed in claim 3, wherein the terminal is an output end, and each of the other ends of the graphene channels is connected to different input ends, respectively.

14. The graphene device as claimed in claim 4, wherein the graphene channels are single-layer graphene thin films.

15. The graphene device as claimed in claim 4, wherein the terminal is an input end, and each of the other ends of the graphene channels is connected to different output ends, respectively.

16. The graphene device as claimed in claim 4, wherein the terminal is an output end, and each of the other ends of the graphene channels is connected to different input ends, respectively.
